(19) United States
(12) Patent Application Publication
(10) Pub. No.: US 2025/0131163 A1
(43) Pub. Date: Apr. 24, 2025

(54) RAMAN PUMP DESIGN USING MACHINE-LEARNING APPROACHES

(71) Applicant: Fujitsu Limited, Kawasaki-shi (JP)

(72) Inventors: Inwoong KIM, Allen, TX (US); Paparao PALACHARLA, Richardson, TX (US); Youichi AKASAKA, Plano, TX (US); Olga I. VASSILIEVA, Plano, TX (US)

(73) Assignee: Fujitsu Limited, Kawasaki-shi (JP)

(21) Appl. No.: 18/492,675

(22) Filed: Oct. 23, 2023

(51) Int. Cl. G06F 30/27

(52) U.S. Cl. CPC G06F 30/27

(57) ABSTRACT

A method may include generating training data corresponding to operation of a Raman pump system. The training data may include input parameters specifying Raman pump parameters and channel launch powers corresponding to respective transmission band channels and an output parameter specifying a Raman pump gain profile of the transmission band channels of the Raman pump system. The method may include training a neural network to output inferred input parameters for the Raman pump system given a specified Raman pump gain profile. The neural network may include an auto-encoder having an input layer with input nodes representing the Raman pump gain profile and the channel launch powers, one or more intermediate layers with intermediate nodes representing the Raman pump parameters and the channel launch powers, and an output layer with output nodes representing the Raman pump gain profile and the channel launch powers.

The present disclosure generally relates to Raman pump design using machine-learning approaches.

### BACKGROUND

An optical fiber is a fiber that is configured to transmit light from a first end of the fiber to a destination at a second end of the fiber. Optical fibers are typically made of glass, particular plastics, or other materials with low indices of refraction such that light may be transmitted through the length of the optical fibers by refracting the light through the optical fibers while mitigating absorption of the light by the fiber itself. Because of the low attenuation of light transmitted through optical fibers and the speed of the propagating light, optical fibers may be useful media for transmitting information from a first location to a remote second location. Optical fibers may be bundled together as cables and used to quickly and accurately facilitate telecommunications and computer networking between many different locations. To facilitate communications via optical fibers, a laser may be emitted through the first end of a particular optical fiber to a receiving element at the second end of the particular optical fiber. A wavelength of the emitted laser in addition to a pulse rate of the emitted laser may be interpreted by the receiving element or an associated computing system to present information at a distant location associated with the second end of the particular optical fiber.

Raman pumps may be used to amplify the output powers of optical signal used in fiber optics communications. Furthermore, Raman pumps may facilitate light transmission of photons having different wavelengths along the same optical fiber. Thus, Raman pumps may improve fiber optics communications by increasing the distances over which optical fibers may communicate information and facilitating multiplexed (i.e., multi-channel) communications along a single optical fiber using photons having different wavelengths. Raman pumps involve emitting a first photon (the “pump photon”) directed towards a second photon (the “Stokes photon”) in which the pump photon is emitted at a particular wavelength specified to excite the Stokes photon. By specifying particular wavelengths for the pump photon, the Stokes photon may be emitted at different wavelengths along an optical fiber.

The subject matter claimed in the present disclosure is not limited to embodiments that solve any disadvantages or that operate only in environments such as those described above. Rather, this background is only provided to illustrate one example technology area where some embodiments described in the present disclosure may be practiced.

### SUMMARY

According to an aspect of an embodiment, a method may include generating training data corresponding to operation of a Raman pump for a distributed Raman amplifier. The training data may include input parameters specifying Raman pump parameters and channel launch powers corresponding to respective transmission band channels and an output parameter specifying a Raman pump gain profile of the transmission band channels of the distributed Raman amplifier where a transmission band can be a single band, such as a C-band, or multi-band including more than two bands, such as the C-band and an L-band. The method may include training a neural network to infer predicted input parameters for the distributed Raman amplifier given a specified Raman pump gain profile. The neural network may include an auto-encoder having an input layer with input nodes representing the Raman pump gain profile and the channel launch powers, one or more intermediate layers with intermediate nodes representing the Raman pump parameters and the channel launch powers, and an output layer with output nodes representing the Raman pump gain profile and the channel launch powers.

The object and advantages of the embodiments will be realized and achieved at least by the elements, features, and combinations particularly pointed out in the claims. It is to be understood that both the foregoing general description and the following detailed description are explanatory and are not restrictive of the invention, as claimed.

### BRIEF DESCRIPTION OF THE DRAWINGS

Example embodiments will be described and explained with additional specificity and detail through the accompanying drawings in which:

FIG. 1 is a diagram of an example operating environment for training a neural network to infer Raman pump parameters given a target Raman pump gain profile according to one or more embodiments of the present disclosure.

FIG. 2 illustrates an example auto-encoder architecture of a neural network configured to infer Raman pump parameters according to one or more embodiments of the present disclosure.

FIG. 3 illustrates an example graph including a simulated Raman pump gain profile based on the Raman pump parameters determined by the neural network in comparison with an estimated Raman pump gain profile determined by the neural network and a target Raman pump gain profile according to one or more embodiments of the present disclosure.

FIG. 4 is a flowchart of an example method of training a neural network to infer Raman pump parameters according to one or more embodiments of the present disclosure.

FIG. 5 is an example computer system according to one or more embodiments of the present disclosure.

### DETAILED DESCRIPTION

Raman pumps are typically designed to emit a pump photon that is capable of exciting a target Stokes photon to a wide range of output wavelengths by inducing a phenomenon known as stimulated Raman scattering in the target Stokes photon. The pump photon is typically emitted at a specific, shorter wavelength relative to a Stokes photon, which may absorb the pump photon while moving through an optical fiber and be re-emitted at a different, longer wavelength. Based on the emission wavelength of the pump photon, a refractive index of a material in which a Raman pump is being operated, and a material associated with the Stokes photon, the re-emission wavelength of the Stokes photon may be specified. Consequently, the Raman pump may emit a first photon at a shorter wavelength based on parameters associated with the Raman pump and a longer target output wavelength of a second photon, while conventional optical lasers are only capable of emitting photons having output wavelengths corresponding to the emission spectra of the material associated with the emitted photons.

The efficiency and effectiveness of a particular Raman pump may be assessed by a Raman gain profile that measures or calculates the Raman gain of the Raman pump. The Raman gain may indicate an optical amplification that arises from the stimulated Raman scattering in the Stokes photon caused by the pump photon in which the Raman gain may be dependent on a frequency offset between a pump wave corresponding to the pump photon and a signal wave corresponding to the Stokes photon. The Raman gain may also depend on other characteristics of the Raman pump, such as the pump wavelength and the material of the optical fiber.

In some situations, one or more Raman pumps may be implemented as distributed Raman amplifiers that are used in conjunction with other optical fiber systems, such as Erbium-Doped Fiber Amplifiers (EDFAs), to increase the optical gain of the optical fiber systems. Increasing the optical gain of the optical fiber system may improve a ratio between the optical signal to noise, or OSNR, because the additional Raman gain strengthens the optical signal without introducing much, if any, additional noise to the optical fiber system. Consequently, a transmission range of the optical signal may be increased by using distributed Raman amplifiers.

When distributed Raman amplifiers are implemented with a Wavelength-Division Multiplexed (WDM) optical fiber that include multiple channels, however, the Raman gain may or may not be uniform across the multiple channels, resulting in some channels having higher gain and better performance than other channels. Multiple Raman pumps may be implemented with the WDM optical fiber to flatten the Raman gain profile across the multiple channels. To improve the uniformity of the Raman gain profile, each Raman pump implemented with the WDM optical fiber may include carefully specified Raman pump wavelengths and pump powers. Designing Raman pumps in WDM optical fibers that involve multi-band transmission may be further complicated because additional stimulated Raman scattering may occur between different band channels, such as between a C-band channel, an L-band channel, an S-band channel, a U-band channel, or any other transmission band channel, and cause interfering effects between two or more of the Raman pumps involved with the WDM optical fibers.

In some situations, Raman pumps may be arranged in a cascading configuration with two or more Raman pumps. A first Raman pump (i.e., a second order or other higher order Raman pump) in such a cascading configuration may emit a first photon having a first wavelength that transfers energy to a second photon (i.e., emitted by a first order or other lower order Raman pump) having a second wavelength that is longer than the first wavelength. The energy provided by the first photon from a higher order Raman pump to the second photon from a lower order Raman pump may increase the Raman gain of the subsequent photon due to the propagation of energy from the first photon to the second photon, resulting in less attenuation in the optical fiber and a greater OSNR.

Furthermore, distributed Raman amplifiers may be implemented with optical fiber systems as forward amplifiers, as backwards amplifiers, or as forward/backwards amplifiers in which forward amplifiers have the optical signal and Raman pump propagate in the same direction while backwards amplifiers have the optical signal and Raman pump propagate in opposite directions.

Modeling distributed Raman amplifiers and especially distributed Raman amplifiers with higher order Raman pumps using computer simulations and machine-learning approaches may improve the efficiency of Raman pump designing. However, machine-learning approaches to designing distributed Raman amplifiers may be inadequate. An output value of the distributed Raman amplifier is often represented by a Raman pump gain profile that indicates an optical gain of the particular distributed Raman amplifier. Different distributed Raman amplifier configurations may yield the same or similar Raman pump gain profiles, which causes a one-to-many mapping problem between the inputted Raman pump parameters and the outputted Raman pump gain profiles that is difficult for existing neural network architectures to resolve. In other words, multiple distributed Raman amplifier configurations with different Raman pump parameters, such as Raman pump wavelengths and pump power configurations, may yield the same or similar Raman pump gain profiles. For example, inverse neural network designs are currently not trained to accurately ascertain which properties or parameters associated with a particular distributed Raman amplifier contributes to generation of a corresponding Raman pump gain profile.

Furthermore, existing machine-learning models for designing distributed Raman amplifiers typically only design distributed Raman amplifiers based on a few Raman pump parameters. For example, the existing machine-learning models may only control for the Raman pump power or a wavelength configuration of the distributed Raman amplifier to generate a target Raman pump gain profile. Existing machine-learning models for designing distributed Raman amplifiers do not specify parameters corresponding to particular channels included in the distributed Raman amplifier, such as channel launch powers.

The present disclosure generally relates to training a neural network to design Raman pumps for distributed Raman amplifiers in multi-band transmission systems. In some embodiments, neural network architectures described according to one or more embodiments of the present disclosure may be used to determine weights associated with input parameters that may or may not influence the Raman pump gain profile. Additionally or alternatively, the neural network architectures of the present disclosure may facilitate training the neural network to consider a wider range input parameters, including channel launch powers and propagation direction, which improves computing performed by the neural network in designing distributed Raman amplifiers by providing more accurate machine-learning models that are configured to consider and analyze a wider variety of input variables.

Embodiments of the present disclosure are explained with reference to the accompanying figures.

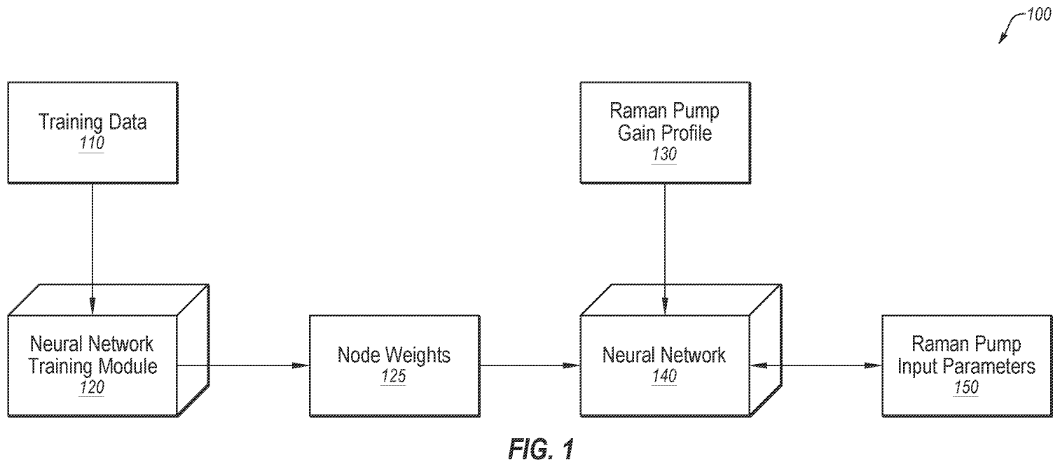

FIG. 1 is a diagram of an example operating environment 100 for training a neural network to infer Raman pump parameters given a target Raman pump gain profile according to one or more embodiments of the present disclosure. The environment 100 may include a neural network training module 120 that is configured to obtain training data 110 and determine node weights 125 corresponding to a trained neural network. The node weights 125 may be used by, implemented with, or otherwise referenced by a neural network 140 that is configured to obtain a Raman pump gain profile 130 and infer Raman pump parameters 150 that could generate the obtained Raman pump gain profile 130.

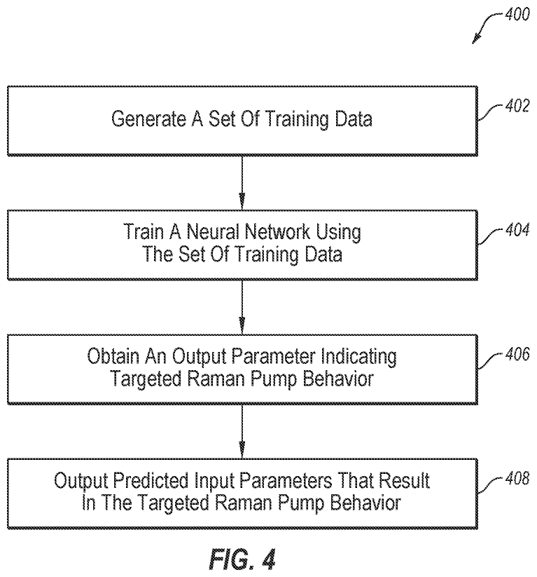

In some embodiments, the neural network training module 120 and/or the neural network 140 (collectively referred to herein as “the computing modules”) may include code and routines configured to enable a computing system to perform one or more operations. Additionally or alternatively, one or more of the computing modules may be implemented using hardware including a processor, a microprocessor (e.g., to perform or control performance of one or more operations), a field-programmable gate array (FPGA), or an application-specific integrated circuit (ASIC). In some other instances, the computing modules may be implemented using a combination of hardware and software. In the present disclosure, operations described as being performed by the computing modules may include operations that the computing modules may direct one or more corresponding systems to perform. The computing modules may be configured to perform a series of operations with respect to the training data 110, the Raman pump gain profile 130, and/or the Raman pump parameters 150 as described in further detail below and in relation to an example method 400 as described with respect to FIG. 4.

In some embodiments, the training data 110 may describe parameters that relate to operations of a distributed Raman amplifier. For example, the training data 110 may include a power specified for a Raman pump or wavelength of the Raman pump. As an additional or alternative example, multi-channel distributed Raman amplifiers, such as those used with WDM optical fiber systems, may involve individual launch powers for the various channels included in the distributed Raman amplifier such that the training data 110 may include channel launch powers. In these and other embodiments, the training data 110 may include input parameters related to the distributed Raman amplifier. In other words, the training data 110 may include parameters that may be set (e.g., by a designing or implementing user) for the distributed Raman amplifier. Based on the input parameters included in the training data 110, output parameters of the distributed Raman amplifier may be determined. For example, a particular set of input parameters may include Raman pump power, Raman pump wavelength, channel launch power, and channel wavelength specifications along with Raman gain and attenuation coefficients of an optical fiber. Solving coupled differential equations based on the particular set of input parameters may result in generating a projected Raman pump gain profile associated with the distributed Raman amplifier.

In some embodiments, the training data 110 may be randomly generated. For example, the Raman pump power, the pump wavelength, and one or more of the channel launch powers may be randomly specified to generate a random Raman pump design. In these and other embodiments, the randomly generated input parameters may respectively yield corresponding, randomly generated Raman pump gain profiles. Randomizing the training data 110 may result in the neural network training module 120 being trained with fewer biases than user-generated Raman pump designs due to user preferences or predispositions. Additionally or alternatively, the randomized training data 110 may result in the neural network training module 120 being trained on a wider range of Raman pump parameters such that a greater number of distributed Raman amplifier configurations may be considered and specified by the neural network training module 120.

The neural network training module 120 may obtain the training data 110 and generate the node weights 125 that indicate an importance of different input parameters in determining a Raman pump gain profile. In some embodiments, the neural network training module 120 may be configured to generate the node weights 125 via a backpropagation training process that involves determining weights that quantify the importance of different variables, represented by intermediate nodes in a particular neural network, in computing the Raman pump gain profile, represented by output nodes in the particular neural network. The neural network training module 120 may assess a difference between an observed Raman pump gain profile corresponding to actual implementation of a distributed Raman amplifier based on input parameters specified in the training data 110 or a simulation of the distributed Raman amplifier based on the input parameters versus a Raman pump gain profile computed according to differential equations based on the input parameters.

In some embodiments, the difference between the observed Raman pump gain profile and the computed Raman pump gain profile may be indicated as a loss value representative of an accuracy of the computed Raman pump gain profile. For example, the loss value may be computed by summing or otherwise combining root mean square differences between the observed and the computed Raman pump gain profiles across some or all of the channels included in the distributed Raman amplifier in which a particular root mean square difference between the observed and the computed Raman pump gain profiles for a particular channel indicates a root mean square error of the computed Raman pump gain profile. If computation of the Raman pump gain profile is considered too inaccurate (e.g., based on the loss value exceeding some threshold value), one or more weights associated with the intermediate nodes representing the input parameters may be adjusted to decrease the loss value the computed Raman pump gain profile and the observed Raman pump gain profile. In these and other embodiments, the neural network training module 120 may be configured to iteratively compare observed Raman pump gain profiles to computed Raman pump gain profiles and iteratively generate updated weight values associated with the intermediate nodes until the loss value is less than a threshold value.

The neural network training module 120 may perform a subsequent backpropagation process to determine weights corresponding to one or more input nodes of a neural network that represent the input parameters associated with the distributed Raman amplifier. In some embodiments, the neural network training module 120 may fix the weights corresponding to the intermediate nodes during the subsequent backpropagation process and iteratively compute loss values corresponding to the input nodes based on differences between observed output values (e.g., observed Raman pump gain profiles) and computed output values (e.g., computed Raman pump gain profiles with the fixed intermediate node weights).

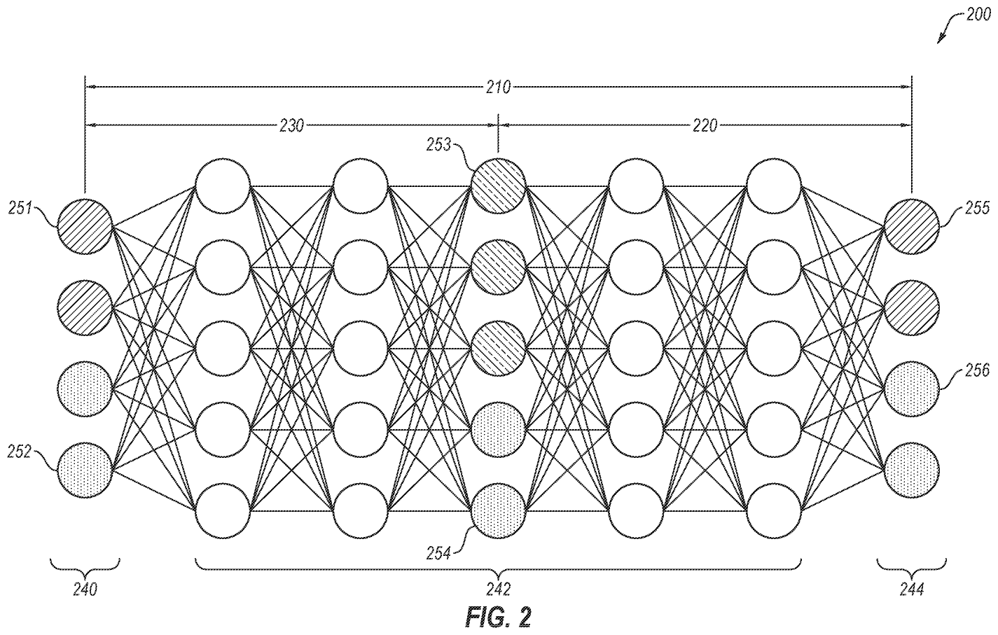

In these and other embodiments, the neural network training module 120 may be configured to determine weights for input nodes, intermediate nodes, and output nodes arranged according to an auto-encoder architecture. FIG. 2 illustrates an example auto-encoder architecture 210 of a neural network 200 configured to infer Raman pump parameters according to one or more embodiments of the present disclosure. The auto-encoder architecture 210 may include a concatenation of an encoder 230, which may be configured for inverse design of distributed Raman amplifiers, and a decoder 220, which may be configured for forward modeling of the distributed Raman amplifiers. The auto-encoder architecture 210 including the encoder 230 concatenated with the decoder 220 may facilitate the neural network 200 performing inverse design of distributed Raman amplifiers by inferring sets of input parameters that may be used to generate a particular target Raman pump gain profile. Additionally or alternatively, the concatenation of the encoder 230 and the decoder 220 may facilitate the neural network 200 performing forward modeling of the distributed Raman amplifiers by computing an inferred Raman pump gain profile given a particular set of input parameters.

In some embodiments, the neural network 200 may include an input layer 240 that includes input nodes, one or more intermediate layers 242 that include intermediate nodes, and an output layer 244 that includes output nodes. In some embodiments, the input nodes may correspond to expected input variables related to designing distributed Raman amplifiers, including input nodes 251 that represent a target Raman pump gain profile and input nodes 252 that represent target parameters of channel launch powers in the C-band, L-band, U-band, S-band, or any other transmission band wavelength ranges of the distributed Raman amplifier. The intermediate nodes may be considered output nodes of the encoder 230 or input nodes of the decoder 220 and may include intermediate nodes 254 that represent the target parameters of the channel launch powers in, for example, the C-band and L-band wavelength ranges of the distributed Raman amplifier within the intermediate layers 242 and intermediate nodes 253 that represent Raman pump parameters. The output nodes may include output nodes 255 that represent the target Raman pump gain profile at the output layer 244 level and output nodes 256 that represent the target parameters of the channel launch powers at the output layer 244 level.

In some embodiments, the output layer 244 may reproduce the information provided at the input layer 240 by having the output nodes 255 and 256 respectively reproduce the input nodes 251 and 252. In other words, the encoder 230 may be configured to generate values corresponding to the intermediate nodes 253 and 254 in the intermediate layer 242 based on provided values corresponding to the input nodes 251 and 252 at the input layer 240. The decoder 220 may be configured to take the values of the intermediate nodes 253 and 254 to reproduce the provided values of the input nodes 251 and 252 as values of the output nodes 255 and 256 at the output layer 244 to verify the inferred values of the intermediate nodes 253 and 254.

In these and other embodiments, including the input nodes 252, the intermediate nodes 254, and the output nodes 256 to represent the target parameters of the channel launch powers in the C-band and L-band wavelength ranges of the distributed Raman amplifier at each layer of the auto-encoder architecture 210 may facilitate the neural network 200 considering launch powers of particular C-band and L-band channels in the designing of the distributed Raman amplifier. Existing neural networks may omit the channel launch parameters in the input layer, the output layer, or both the input layer and the output layer, which may or may not result in the channel launch powers not being accurately or appropriately specified according to target functionality of the distributed Raman amplifier being designed. Because different distributed Raman amplifier configurations including different channel launch parameters may result in the same Raman pump gain profile, existing neural networks that do not consider the channel launch parameters in the input layer or the output layer may fail to provide practical channel launch powers. For example, the channel launch powers may be set to low values to decrease or otherwise remove the influence of the channel launch powers on the designed distributed Raman amplifier, which may result in the designed distributed Raman amplifier failing to meet one or more target performance expectations. By representing the channel launch power parameters as the input nodes 252, the intermediate nodes 254, and the output nodes 256, channel launch powers of any C-band or L-band channels included in the designed distributed Raman amplifier may be specified more accurately.

Returning to the description of FIG. 1, the node weights 125 set by the neural network training module 120 may be implemented with the neural network 140, which may be the same as or similar to the neural network 200 described in relation to FIG. 2. For example, the neural network 140 may include an auto-encoder architecture as described in relation to the neural network 200, and the node weights 125 may correspond to the weights of the nodes included in the input layer 240, the intermediate layers 242, and the output layer 244. As such, the neural network 140 may be configured to predictively compute Raman pump gain profiles given Raman pump input parameters and vice versa.

The neural network 140 may be configured to obtain the Raman pump gain profile 130 and output the Raman pump input parameters 150. Additionally or alternatively, the neural network 140 may be configured to obtain the Raman pump input parameters 150 and output the Raman pump gain profile 130. In some embodiments, a design of a distributed Raman amplifier may be evaluated in light of the output of the neural network 140 (e.g., the Raman pump gain profile 130 or the Raman pump input parameters 150). For example, a particular distributed Raman amplifier designed based on Raman pump input parameters specified by the neural network 140 may be evaluated by comparing a Raman pump gain profile computed based on the specified Raman pump input parameters against a target Raman pump gain profile, such as by computing a loss value between the computed and the target Raman pump gain profiles. Responsive to the computed and the target Raman pump gain profiles being different (e.g., the comparison including a loss value greater than a threshold value), the node weights 125 used by the neural network 140 may be updated, such as by the neural network training module 120.

Modifications, additions, or omissions may be made to the environment 100 without departing from the scope of the present disclosure. For example, the designations of different elements in the manner described is meant to help explain concepts described herein and is not limiting. For instance, in some embodiments, the training data 110, the Raman pump gain profile 130, and/or the Raman pump parameters 150 are delineated in the specific manner described to help with explaining concepts described herein but such delineation is not meant to be limiting. Further, the environment 100 may include any number of other elements or may be implemented within other systems or contexts than those described.

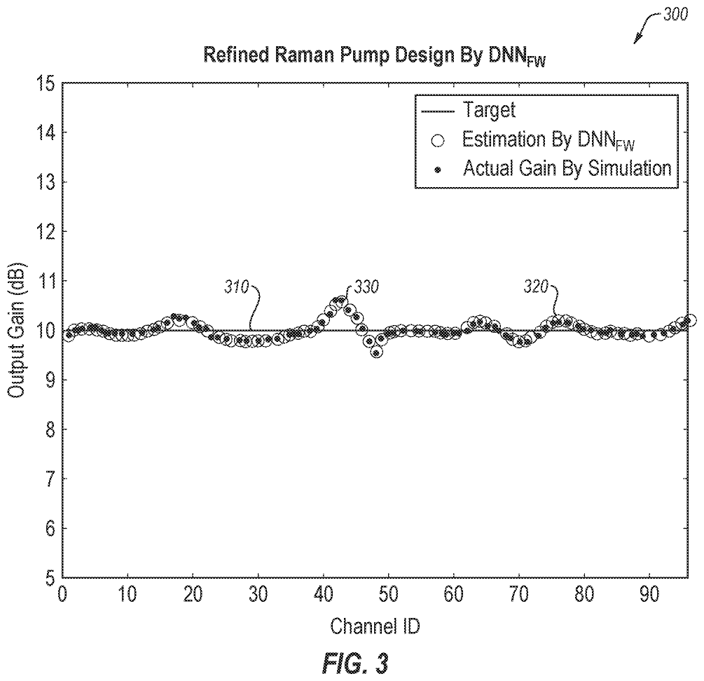

FIG. 3 illustrates an example graph 300 including a simulated Raman pump gain profile 330 based on the Raman pump parameters determined by the neural network in comparison with an estimated Raman pump gain profile 320 determined by the neural network and a target Raman pump gain profile 310 according to one or more embodiments of the present disclosure. The target Raman pump gain profile 310 may indicate a target gain level at which the distributed Raman amplifier corresponding to the target Raman pump gain profile 310 is to be set. As illustrated in the graph 300, the target Raman pump gain profile 310 indicates that the distributed Raman amplifier is to be set at 10 decibels (dB).

The estimated Raman pump gain profile 320 may be provided by a neural network, such as the neural network 140 of FIG. 1 or the neural network 200 of FIG. 2, that infers Raman pump input parameters according to the target Raman pump gain profile 310. As illustrated in the graph 300, for example, an estimated Raman pump gain profile 320 that corresponds to the target Raman pump gain profile 310 may include output gains across multiple channels that, on average, are set to approximately 10 dB. In some embodiments, the estimated Raman pump gain profile 320 may be generated by running the neural network.

Additionally or alternatively, the graph 300 illustrates a fine-tuned Raman pump gain profile 330 that is observed by simulating a distributed Raman amplifier according to the Raman pump input parameters inferred by the neural network. The fine-tuned Raman pump gain profile 330 may be compared to the estimated Raman pump gain profile 320 to determine whether the Raman pump input parameters that yielded the estimated Raman pump gain profile 320 and the fine-tuned Raman pump gain profile 330 are the same or similar within a particular threshold. As illustrated in the graph 300, the estimated Raman pump gain profile 320, which is generated by a trained neural network according to one or more embodiments of the present disclosure, and the fine-tuned Raman pump gain profile 330 largely include the same or similar Raman pump gain profiles, indicating that the neural network has generated Raman pump input parameters that correspond to the target Raman pump gain profile 310.

FIG. 4 is a flowchart of an example method 400 of training a neural network to infer Raman pump parameters according to one or more embodiments of the present disclosure. The method 400 may be performed by any suitable system, apparatus, or device. For example, the training data 110, the Raman pump gain profile 130, and/or the Raman pump parameters 150 of FIG. 1 may perform one or more operations associated with the method 400. Although illustrated with discrete blocks, the steps and operations associated with one or more of the blocks of the method 400 may be divided into additional blocks, combined into fewer blocks, or eliminated, depending on the particular implementation.

The method 400 may begin at block 402, where training data corresponding to operation of a distributed Raman amplifier is generated. In some embodiments, the training data may include training input parameters that specify Raman pump parameters, such as a signal wavelength or a Raman pump power, and channel launch powers corresponding to respective C-band channels or L-band channels included in the distributed Raman amplifier. Additionally or alternatively, the training data may include a training output parameter that specifies a Raman pump gain profile of the C-band channels and the L-band channels of the distributed Raman amplifier. In some embodiments, the training data may include randomly generated Raman pump parameters, and a Raman pump gain profile may be computed based on the randomly generated Raman pump parameters by solving coupled differential equations associated with the Raman pump parameters.

In some embodiments, a training data set may be generated in a test bed that includes Raman pump and multi-band channel transmission links. In the test bed, random Raman pump parameters may be set in a particular range, such as a range of parameter values representative of typical Raman pump operations. In these and other embodiments, the range of parameter values included in the particular range may be set based on constraints involved with a corresponding Raman pump. For example, Raman pump wavelength or pump power parameters may be set to a limited range of possible values to account for manufacturing problems associated with a particular Raman pump. As an additional or alternative example, Raman pump parameters may be limited to avoid damaging an optical fiber due to excessive power input. Based on the randomly set Raman pump parameters from the test bed, the Raman pump gain profile may be measured. The setting and random selection of possible Raman pump parameters may be repeated a particular number of times to generate the training data set.

At block 404, a neural network may be trained using the training data such that the neural network is configured to output inferred input parameters for the distributed Raman amplifier given a particular Raman pump gain profile. Additionally or alternatively, the neural network may be trained to output a Raman pump gain profile given a particular set of Raman pump parameters.

In some embodiments, the neural network may include an auto-encoder that has an input layer with input nodes representing the Raman pump gain profile and the channel launch powers, one or more intermediate layers with intermediate nodes representing the Raman pump parameters and the channel launch powers, and an output layer with output nodes representing the Raman pump gain profile and the channel launch powers. The auto-encoder may include an encoder between the input layer and the intermediate layer and a decoder between the intermediate layer and the output layer. Training the auto-encoder may involve using a backpropagation process in which decoding weights associated with nodes of the intermediate and output layers associated with the decoder are set based on a particular Raman pump gain profile and encoding weights associated with nodes of the input and intermediate layers associated with the encoder are set based on the nodes included in the intermediate layer and their respective decoding weights.

At block 406, the trained neural network may obtain an output parameter indicating a targeted Raman pump gain profile.

At block 408, the trained neural network may output inferred Raman pump parameters that result in the distributed Raman amplifier exhibiting behavior corresponding to the targeted Raman pump gain profile indicated by the obtained output parameter.

In some embodiments, the trained neural network may be improved, fine-tuned, or otherwise modified. A first Raman pump gain profile corresponding to a simulated distributed Raman amplifier having the inferred Raman pump parameters may be compared with a second Raman pump gain profile output by the neural network alongside the inferred Raman pump parameters. The comparison between the first and the second Raman pump gain profiles may be based on a root mean square error between the two Raman pump gain profiles and quantitatively represented as a loss value. In some embodiments, responsive to the loss value being greater than a particular threshold value, weights associated with the nodes of the neural network, such as the intermediate nodes representing Raman pump parameters and channel launch powers of a decoder, may be fixed, while Raman pump input parameters obtained by an encoder may be fine-tuned to update the second Raman pump gain profile to be more similar to the first Raman pump gain profile.

Modifications, additions, or omissions may be made to the method 500 without departing from the scope of the disclosure. For example, the designations of different elements in the manner described is meant to help explain concepts described herein and is not limiting. Further, the method 500 may include any number of other elements or may be implemented within other systems or contexts than those described.

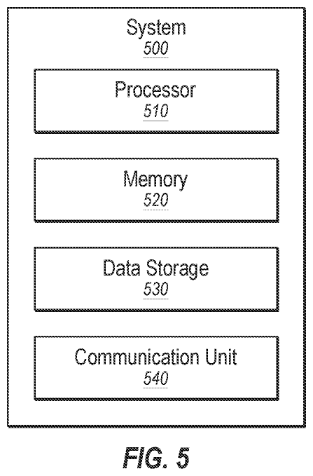

FIG. 5 is an example computer system 500 according to one or more embodiments of the present disclosure. The computing system 500 may include a processor 510, a memory 520, a data storage 530, and/or a communication unit 540, which all may be communicatively coupled. Any or all of the environment 100 of FIG. 1 may be implemented as a computing system consistent with the computing system 500.

Generally, the processor 510 may include any suitable special-purpose or general-purpose computer, computing entity, or processing device including various computer hardware or software modules and may be configured to execute instructions stored on any applicable computer-readable storage media. For example, the processor 510 may include a microprocessor, a microcontroller, a digital signal processor (DSP), an application-specific integrated circuit (ASIC), a Field-Programmable Gate Array (FPGA), or any other digital or analog circuitry configured to interpret and/or to execute program instructions and/or to process data.

Although illustrated as a single processor in FIG. 5, it is understood that the processor 1010 may include any number of processors distributed across any number of network or physical locations that are configured to perform individually or collectively any number of operations described in the present disclosure. In some embodiments, the processor 510 may interpret and/or execute program instructions and/or process data stored in the memory 520, the data storage 530, or the memory 520 and the data storage 530. In some embodiments, the processor 510 may fetch program instructions from the data storage 530 and load the program instructions into the memory 520.

After the program instructions are loaded into the memory 520, the processor 510 may execute the program instructions, such as instructions to cause the computing system 500 to perform the operations of the method 500 of FIG. 5. For example, the computing system 500 may execute the program instructions to generate a set of training data, train a neural network using the set of training data, obtain an output parameter indicating targeted Raman pump behavior, and/or output inferred input parameters that result in the targeted Raman pump behavior.

The memory 520 and the data storage 530 may include computer-readable storage media or one or more computer-readable storage mediums for having computer-executable instructions or data structures stored thereon. Such computer-readable storage media may be any available media that may be accessed by a general-purpose or special-purpose computer, such as the processor 510. For example, the memory 520 and/or the data storage 530 may include the high-training data 110, the Raman pump gain profile 130, and/or the Raman pump parameters 150 of FIG. 1. In some embodiments, the computing system 500 may or may not include either of the memory 520 and the data storage 530.

By way of example, and not limitation, such computer-readable storage media may include non-transitory computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, flash memory devices (e.g., solid state memory devices), or any other storage medium which may be used to store desired program code in the form of computer-executable instructions or data structures and which may be accessed by a general-purpose or special-purpose computer. Combinations of the above may also be included within the scope of computer-readable storage media. Computer-executable instructions may include, for example, instructions and data configured to cause the processor 510 to perform a particular operation or group of operations.

The communication unit 540 may include any component, device, system, or combination thereof that is configured to transmit or receive information over a network. In some embodiments, the communication unit 540 may communicate with other devices at other locations, the same location, or even other components within the same system. For example, the communication unit 540 may include a modem, a network card (wireless or wired), an optical communication device, an infrared communication device, a wireless communication device (such as an antenna), and/or chipset (such as a Bluetooth device, an 802.6 device (e.g., Metropolitan Area Network (MAN)), a WiFi device, a WiMax device, cellular communication facilities, or others), and/or the like. The communication unit 540 may permit data to be exchanged with a network and/or any other devices or systems described in the present disclosure. For example, the communication unit 540 may allow the system 500 to communicate with other systems, such as computing devices and/or other networks.

One skilled in the art, after reviewing this disclosure, may recognize that modifications, additions, or omissions may be made to the system 500 without departing from the scope of the present disclosure. For example, the system 500 may include more or fewer components than those explicitly illustrated and described.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, it may be recognized that changes may be made in form and detail without departing from the scope of the present disclosure. Thus, the present disclosure is limited only by the claims.

In some embodiments, the different components, modules, engines, and services described herein may be implemented as objects or processes that execute on a computing system (e.g., as separate threads). While some of the systems and processes described herein are generally described as being implemented in software (stored on and/or executed by general purpose hardware), specific hardware implementations or a combination of software and specific hardware implementations are also possible and contemplated.

Terms used in the present disclosure and especially in the appended claims (e.g., bodies of the appended claims) are generally intended as “open terms” (e.g., the term “including” should be interpreted as “including, but not limited to.”).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is expressly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase preceding two or more alternative terms, whether in the description, claims, or drawings, should be understood to contemplate the possibilities of including one of the terms, either of the terms, or both of the terms. For example, the phrase “A or B” should be understood to include the possibilities of “A” or “B” or “A and B.”

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although embodiments of the present disclosure have been described in detail, various changes, substitutions, and alterations could be made hereto without departing from the spirit and scope of the present disclosure.

What is claimed is:

1. A method, comprising:
generating training data corresponding to operation of a Raman pump system, the training data including:
training input parameters specifying Raman pump parameters and one or more channel launch powers corresponding to respective transmission band channels; and
a training output parameter specifying a Raman pump gain profile of the transmission band channels of the Raman pump system; and
training a neural network using the training data such that the neural network is configured to output inferred input parameters for the Raman pump system given a specified Raman pump gain profile.

2. The method of claim 1, wherein the neural network includes an auto-encoder that comprises:
an input layer having input nodes representing the Raman pump gain profile and the channel launch powers;
one or more intermediate layers having intermediate nodes representing the Raman pump parameters and the channel launch powers; and
an output layer having output nodes representing the Raman pump gain profile and the channel launch powers.

3. The method of claim 2, wherein the auto-encoder of the neural network includes an encoding function between the input layer and the intermediate layer and a decoding function between the intermediate layer and the output layer and is trained using a backpropagation process that involves:
setting decoding weights associated with the decoding function and the one or more intermediate layers based on the Raman pump gain profile of the output layer; and
setting encoding weights associated with the encoding function and the one or more intermediate layers based on the decoding weights.

4. The method of claim 2, further comprising comparing a first Raman pump gain profile corresponding to a simulated Raman pump system having the inferred input parameters output by the neural network to a second Raman pump gain profile output by the neural network alongside the inferred input parameters, the comparing the first Raman pump gain profile to the second Raman pump gain profile being based on a root mean square error between the first Raman pump gain profile and the second Raman pump gain profile.

5. The method of claim 4, further comprising adjusting weights associated with the input nodes, the intermediate nodes, or the output nodes responsive to the first Raman pump gain profile and the second Raman pump gain profile differing by a threshold value.

6. The method of claim 1, further comprising:
obtaining, by the trained neural network, an output parameter indicating a targeted Raman pump gain profile; and
outputting, by the trained neural network, the inferred input parameters that result in the Raman pump system exhibiting behavior corresponding to the targeted Raman pump gain profile indicated by the obtained output parameter.

7. The method of claim 1, wherein the Raman pump parameters include a Raman pump wavelength and a Raman pump power.

8. The method of claim 1, wherein:
the training data is randomly generated; and
the Raman pump gain profile is computed by solving coupled differential equations associated with the input parameters.

9. The method of claim 1, wherein:
the training data is generated in a test bed that:
generates random values of the training input parameters; and
measures the Raman pump gain profile based on the Raman pump system being designed with the random values; and
the test bed repeatedly generates the random values of the training input parameters and measures the Raman pump gain profile for a particular number of times.

10. A method, comprising:
obtaining, by a neural network, an output parameter indicating a targeted Raman pump gain profile corresponding to a Raman pump system; and
outputting, by the neural network, inferred input parameters that result in the Raman pump system exhibiting behavior corresponding to the targeted Raman pump gain profile indicated by the obtained output parameter, the inferred input parameters including Raman pump parameters and one or more channel launch powers corresponding to respective transmission band channels of the Raman pump system.

11. The method of claim 10, wherein the neural network includes an auto-encoder that comprises:
an input layer having input nodes representing the Raman pump gain profile and the channel launch powers;
one or more intermediate layers having intermediate nodes representing the Raman pump parameters and the channel launch powers; and
an output layer having output nodes representing the Raman pump gain profile and the channel launch powers.

12. The method of claim 11, wherein the auto-encoder of the neural network includes an encoding function between the input layer and the intermediate layer and a decoding function between the intermediate layer and the output layer and is trained using a backpropagation process that involves:
setting decoding weights associated with the decoding function and the one or more intermediate layers based on the Raman pump gain profile of the output layer; and
setting encoding weights associated with the encoding function and the one or more intermediate layers based on the decoding weights.

13. The method of claim 11, further comprising comparing a first Raman pump gain profile corresponding to a simulated Raman pump system having the inferred input parameters output by the neural network to a second Raman pump gain profile output by the neural network alongside the inferred input parameters, the comparing the first Raman pump gain profile to the second Raman pump gain profile being based on a root mean square error between the first Raman pump gain profile and the second Raman pump gain profile.

14. The method of claim 13, further comprising adjusting weights associated with the input nodes, the intermediate nodes, or the output nodes responsive to the first Raman pump gain profile and the second Raman pump gain profile differing by a threshold value.

15. The method of claim 10, wherein the Raman pump parameters include a Raman pump wavelength and a Raman pump power.

16. A system, comprising:
a neural network configured to output inferred input parameters for a Raman pump system given a specified Raman pump gain profile, the neural network including an auto-encoder that includes:
an input layer having input nodes representing the Raman pump gain profile and channel launch powers;
one or more intermediate layers having intermediate nodes representing the Raman pump parameters and the channel launch powers; and
an output layer having output nodes representing the Raman pump gain profile and the channel launch powers;
one or more processors; and
one or more non-transitory computer-readable storage media configured to store instructions that, in response to being executed, cause the system to perform operations, the operations comprising:
generating training data corresponding to operation of the Raman pump system, the training data including:
training input parameters specifying Raman pump parameters and one or more channel launch powers corresponding to transmission band channels; and
a training output parameter specifying a Raman pump gain profile of the transmission band channels of the Raman pump system; and
training a neural network using the training data such that the neural network is configured to output inferred input parameters for the Raman pump system given a specified Raman pump gain profile.

17. The system of claim 16, wherein the auto-encoder of the neural network includes an encoding function between the input layer and the intermediate layer and a decoding function between the intermediate layer and the output layer and is trained using a backpropagation process that involves:
setting decoding weights associated with the decoding function and the one or more intermediate layers based on the specified Raman pump gain profile of the output layer; and
setting encoding weights associated with the encoding function and the one or more intermediate layers based on the decoding weights.

18. The system of claim 17, further comprising comparing a first Raman pump gain profile corresponding to a simulated Raman pump system having the inferred input parameters output by the neural network to a second Raman pump gain profile output by the neural network alongside the inferred input parameters, the comparing the first Raman pump gain profile to the second Raman pump gain profile being based on a root mean square error between the first Raman pump gain profile and the second Raman pump gain profile.

19. The system of claim 18, further comprising adjusting weights associated with the input nodes, the intermediate nodes, or the output nodes responsive to the first Raman pump gain profile and the second Raman pump gain profile differing by a threshold value.

20. The system of claim 16, wherein the Raman pump parameters include Raman pump wavelength and a Raman pump power.

21. The system of claim 16, wherein:
the training data is randomly generated; and
the Raman pump gain profile is computed by solving coupled differential equations associated with the input parameters.
